(19) United States
(12) Patent Application Publication
(10) Pub. No.: US 2007/0152573 A1
(43) Pub. Date: Jul. 5, 2007

(54) Polymer organic light-emitting device

(76) Inventors: Mu-Gyeom Kim, Hwaseong-si (KR); Jhun-Mo Son, Yongin-si (KR); Sang-Hoon Park, Seongnam-si (KR); Joon-Yong Park, Yongin-si (KR); Tae-Woo Lee, Seoul (KR); Sang-Yeol Kim, Gwacheon-si (KR)

Correspondence Address: Robert E. Bushnell, Suite 300, 1522 K Street, N.W., Washington, DC, 20005-1202, US

(21) Appl. No.: 11/589,052

(22) Filed: Oct. 30, 2006

(30) Foreign Application Priority Data
Jan. 5, 2006 (KR) 10-2006-0001390

(51) Int. Cl. H01L 51/00

(52) U.S. Cl. 313/506

(57) ABSTRACT

A polymer organic light-emitting device (OLED) is provided to improve efficiency and lifetime of the polymer OLED by preventing the recombination zone from shrinking. The OLED includes a first electrode, a second electrode, and an emission layer disposed between the first electrode and the second electrode. The emission layer includes an emission material and a hole transport material. The emission layer can be built in a single layer or in multi-layers. In the multi-layer structure, one layer includes an emission material and a hole transport material, while the other layer includes an emission material. The polymer OLED presented in this invention exhibits superior properties regarding electron density, brightness, and color purity.

### CLAIM OF PRIORITY

This application claims the benefit of Korean Patent Application No. 10-2006-0001390, filed on Jan. 5, 2006, in the Korean Intellectual Property Office, the disclosure of which is incorporated herein in its entirety by reference.

### BACKGROUND OF THE INVENTION

1. Field of the Invention

The present invention relates to a polymer organic light-emitting device (polymer OLED) including a hole transport material in an emission layer, and more particularly, to a polymer OLED including a hole transport material having an excellent hole transport capability in an emission layer and exhibiting improved properties such as electron density, brightness and color purity.

2. Description of the Related Art

A light-emitting device is a self light-emitting type device which has numerous advantages including wide viewing angle, superior contrast, and fast response time. A light-emitting device may be classified as an inorganic light-emitting device using inorganic compounds for an emission layer or an organic light-emitting device (OLED) using organic compounds for an emission layer. OLEDs have been widely studied because of their superior properties compared to inorganic light-emitting devices, such as brightness, driving voltage and response time, and their capability of displaying multi-color images.

An OLED generally has a stacked structure such as a stack of anode/organic emission layer/cathode. Herein, a slash character (‘/’) denotes an interface between two adjacent layers. For example, the stack of anode/organic emission layer/cathode means that a cathode is formed on an organic emission layer and the organic emission layer is formed on an anode in the stack. Because of the upside down symmetry of the stacked layers, reverse order of the listed layers will represent the same stack.

It may also have various other structures such as a stack of anode/hole injection layer/hole transport layer/emission layer/electron transport layer/electron injection layer/cathode, or a stack of anode/hole injection layer/hole transport layer/emission layer/hole blocking layer/electron transport layer/electron injection layer/cathode.

Furthermore, OLEDs may be classified as low molecular OLEDs which use materials of low molecular weight, or high molecular OLEDs (or polymer OLEDs) which use materials of high molecular weight (polymer), according to materials of their organic layer and fabrication process. Low molecular OLEDs have several advantages such as that their organic layers may be formed by vacuum deposition, their light-emitting layers may be easily purified to have a high purity, and full-color displays may be easily achieved. However, for practical purposes, low molecular OLEDs need, among other requirements, improved quantum efficiency, suppressed crystallization of thin films, and improved color purity.

On the other hand, research into polymer OLEDs has accelerated since it was first reported that poly(1,4-phenylenevinylene) (PPV), as a π-conjugate polymer, emits light when electricity is applied thereto. The π-conjugate polymer has a chemical structure with an alternate single bond (or σ bond) and double bond (or π bond), and therefore π electrons are capable of relatively freely moving along the bond chain without being localized. Because of the semi-conducting properties of the π-conjugate polymer, when the π-conjugate polymer is applied to a light-emitting layer, entire range of visible light, which corresponds to a band-gap of the highest occupied molecular orbital and lowest unoccupied molecular orbital (HOMO-LUMO), can be obtained by properly designing molecular structures. Also, thin films of the π-conjugate polymer can be formed by a spin coating or printing method, which allows easier and cheaper manufacturing processes. Furthermore, since such polymers usually have high glass transition temperatures (Tg), thin films of the polymers have good mechanical properties.

However, OLEDs that are made of conventional polymers have relatively higher electron mobility than hole mobility during operation, which causes holes and electrons to meet each other near an anode side in an emission layer. Thus, the recombination zone of holes and electrons is localized at a region near the anode. On the other hand, when the OLEDs that are made of conventional polymers are operated, cross-linking between polymer chains, which is caused by electro-chemical reactions, is generated at the region near the anode, which results in the generation of an insoluble layer. Such an insoluble layer lowers the hole mobility, which results in a decrease in the number of holes that can be transported into the recombination zone. As a result, the recombination zone becomes smaller, and the efficiency and the lifetime of the OLEDs decrease.

Thus, there is need for a method to improve efficiency and lifetime of the device by preventing the recombination zone from shrinking due to the generation of an insoluble layer.

### SUMMARY OF THE INVENTION

The present invention provides a polymer organic light-emitting device (OLED) which has improved properties of electron density, luminance and color purity.

According to an aspect of the present invention, there is provided a polymer OLED including a first electrode, a second electrode, and an emission layer disposed between the first electrode and the second electrode. The emission layer includes an emission material and a hole transport material.

The hole transport material in the polymer OLED may have a hole mobility in the range of 10⁻⁵ cm²V⁻¹s⁻¹-10⁻⁷ cm²V⁻¹s⁻¹, and a highest occupied molecular orbital energy level of −5.5 eV- −5.9 eV. The emission layer in the polymer OLED may have a glass transition temperature of 100° C. to 300° C. The content of the hole transport material in the emission layer may be 0.1 weight % to 10 weight % of the total weight of the emission layer.

The emission layer in the polymer OLED can have either a single-layered structure or a multi-layered structure.

The emission layer in the polymer OLED that has a single-layered structure has a thickness of 50 nm to 120 nm.

The emission layer in the polymer OLED can have a multi-layered structure. The multi-layered emission layer includes a first emission layer including an emission material and a hole transport material, and a second emission layer including an emission material. The total thickness of the emission layer is in the range of 60 nm to 120 nm, and the thickness of the first emission layer is in the range of 10 nm to 50 nm.

The polymer OLED can further include at least one layer, between the first electrode and the second electrode, such as a hole injection layer, a hole transport layer, an electron blocking layer, a hole blocking layer, an electron transport layer, or an electron injection layer.

The polymer OLED can further include a structure such as a stack of first electrode/hole transport layer/emission layer/second electrode, a stack of first electrode/hole injection layer/emission layer/electron transport layer/electron injection layer/second electrode, a stack of first electrode/hole injection layer/hole transport layer/emission layer/electron transport layer/electron injection layer/second electrode, or a stack of first electrode/hole injection layer/hole transport layer/emission layer/hole blocking layer/electron transport layer/electron injection layer/second electrode.

The emission layer in the polymer OLED may contain phosphorescent or fluorescent dopants, each of which includes a red, green, blue or white dopant.

The hole transport material in the polymer OLED can be at least one polymer such as PVKs, phenoxazine based polymer, or triphenylamine based polymer.

The polymer OLED of the present invention, in which a emission layer includes a hole transport polymeric material, provides improved properties of electron density, brightness, and color purity, and these properties are not deteriorated in spite of the generation of an insoluble layer within the emission layer.

### BRIEF DESCRIPTION OF THE DRAWINGS

The above and other features and advantages of the present invention will become more apparent by describing in detail exemplary embodiments thereof with reference to the attached drawings.

FIGS. 1A through 1D are cross-sectional views of the structures of polymer organic light-emitting devices (OLEDs) constructed as embodiments of the present invention.

### DETAILED DESCRIPTION OF THE INVENTION

Hereinafter, the present invention will be described in detail by explaining embodiments of the invention with reference to the attached drawings.

According to an embodiment of the present invention, a polymer organic light-emitting device (OLED) includes a first electrode, a second electrode, and an emission layer between the first electrode and the second electrode. The emission layer includes an emission material and a hole transport material. The emission layer has excellent hole transport capability by including the hole transport material. Therefore, the mobility of holes moving toward the emission layer is not reduced in spite of the generation of an insoluble layer produced during an operation of the polymer OLED. That is, in spite of the generation of the insoluble layer near an anode side in the emission layer, a recombination zone of holes and electrons in the emission layer doses not shift toward a cathode and the size of the recombination zone does not decrease, which makes it possible to more efficiently use the entire emission layer.

The hole transport material included in the emission layer is a conducting polymer whose average molecular weight (Mn) may be in the range of 1400 to 200,000. When the molecular weight is less than 1400, the polymer may not have suitable mechanical properties required for the use in a display device. When the molecular weight is greater than 200,000, the polymer may be difficult to mold, which is not appropriate for practical use.

The hole transport material included in the emission layer can be either the same as or different from a material that forms a transport layer which will be described later.

In the polymer OLED constructed as an current embodiment of the present invention, the hole transport material may have a hole mobility in the range of about 10⁻⁵ cm²V⁻¹s⁻¹-10⁻⁷ cm²V⁻¹s⁻¹ and may have a highest occupied molecular orbital (HOMO) energy level in the range of about −5.5 eV-about −5.9 eV.

When the hole mobility of the hole transport material is greater than 10⁻⁵ cm²V⁻¹s⁻¹, an emission zone may become so wide that charges of holes and electrons may not be balanced. When the hole mobility is less than 10⁻⁷ cm²V⁻¹s⁻¹, the emission zone may become so narrow that charges of holes and electrons may not be balanced. When the HOMO energy level of the hole transport material is greater than −5.5 eV, a hole injecting barrier toward the emission layer may increase. When the HOMO energy level of the hole transport material is less than −5.9 eV, another hole injecting barrier from a hole injection layer may increase. In the polymer OLED constructed as the current embodiment of the present invention, the glass temperature (Tg) of the hole transport material may be in the range of about 100° C.-300° C. When the glass temperature of the hole transport material is less than 100° C., there may be a problem of thermal instability. When the glass temperature of the hole transport material is higher than 300° C., the electroluminescent (EL) efficiency of the emission layer may decrease.

In the polymer OLED constructed according to the principles of the current embodiment of the present invention, the content of the hole transport material in the emission may be about 0.1 weight % to about 10 weight % of the total weight of the emission layer.

When the content of the hole transport material in the emission layer is less than 0.1 weight %, the hole transport material may not have a hole transport capability. When the content of the hole transport material in the emission layer is greater than 10 weight %, the stability of the hole transport material and the EL efficiency of the emission layer may be deteriorated.

The emission layer of the polymer OLED may have a single-layered structure or a multi-layered structure according to an embodiment of the present invention.

In a polymer OLED constructed as an embodiment of the present invention, an emission layer has a single-layered structure. The single emission layer has a thickness of about 50 nm to about 120 nm. When the thickness of the emission layer having a single-layered structure is less than 50 nm, the EL efficiency may be lowered by current leakage. When the thickness of the emission layer having a single-layered structure is greater than 120 nm, the EL efficiency may also be lowered by high voltage.

In a polymer OLED constructed as another embodiment of the present invention, an emission layer has a multi-layered structure. The multi-layered emission layer includes a first emission layer containing an emission material and a hole transport material, and a second emission layer containing an emission material. The second emission layer can be formed between the first emission layer and the second electrode, but the order of the first and the second emission layers can be changed if necessary. The total thickness of the emission layer (sum of the thicknesses of the first and second emission layers) may be in the range of about 60 nm to 120 nm and the thickness of the first emission layer is in the range of 10 nm to 50 nm. The content of the hole transport material in the first emission layer is between about 0.1 weight % and about 10 weight % of the total weight of the first emission layer.

When the total thickness of the emission layer having a multi-layered structure is less than 60 nm, the EL efficiency may be lowered by current leakage. When the total thickness of the emission layer having a multi-layered structure is greater than 120 nm, the EL efficiency may also be lowered by high voltage. When the thickness of the first emission layer is less than 10 nm, the EL efficiency may be lowered by hole tunneling effect. When the thickness of the first emission layer is greater than 50 nm, the EL efficiency may also be lowered by a voltage increase.

In this embodiment, two emission layers (the first and the second emission layers) are described, but it is also possible to include more than two emission layers if necessary to improve the efficiency of the OLED. Various configurations of the emission layers can be designed with respect to the contents of the emission material and the hole transport material and with respect to the thickness of each of the emission layers.

The polymer OLEDs constructed according to the principles of the embodiments of the present invention have various structures and may further includes at least one layer such as a hole injection layer, a hole transport layer, an electron blocking layer, a hole blocking layer, an electron transport layer, or an electron injection layer between the first electrode and the second electrode.

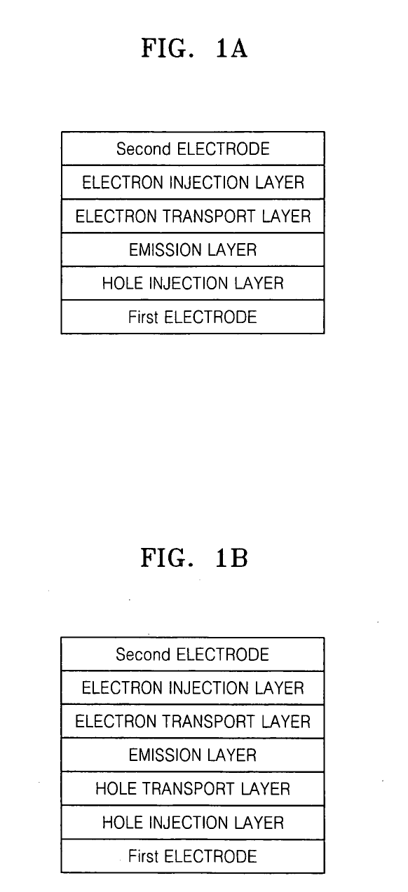

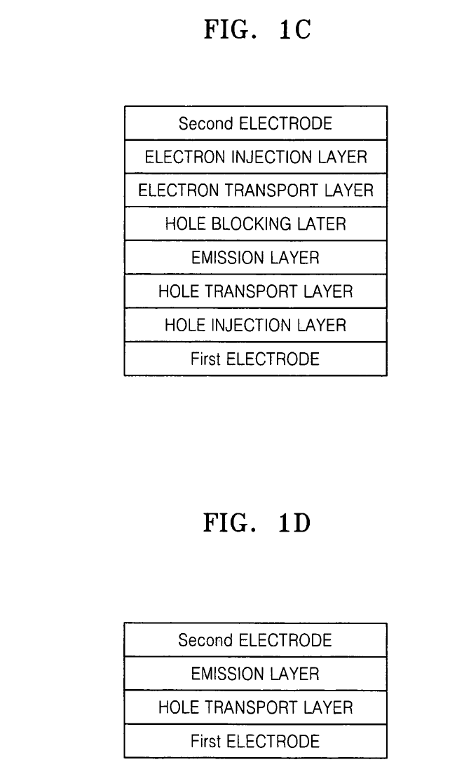

FIGS. 1A through 1D are cross-sectional views of the structure of polymer organic light-emitting devices (OLEDs) that can be constructed as embodiments of the present invention. The polymer OLED shown in FIG. 1A has a structure of first electrode/hole injection layer/emission layer/electron transport layer/electron injection layer/second electrode, and the polymer OLED shown in FIG. 1B has a structure of first electrode/hole injection layer/hole transport layer/emission layer/electron transport layer/electron injection layer/second electrode. The OLED shown in FIG. 1C has a structure of first electrode/hole injection layer/hole transport layer/emission layer/hole blocking layer/electron transport layer/electron injection layer/second electrode. The emission layers described above can include the hole transport material as previously described according to an embodiment of the present invention, and can have multi-layered structure as described according to another embodiment of the present invention.

The emission layer of the OLEDs constructed according to the principles of the present invention may contain phosphorescent or fluorescent dopant, each of which includes red, green, blue or white dopant. The phosphorescent dopants may be organo-metallic compounds containing at least one element such as iridium (Ir), platinum (Pt), osmium (Os), titanium (Ti), zirconium (Zr), hafnium (Hf), europium (Eu), terbium (Tb), or thulium (Tm).

The hole transport material in the polymer OLEDs constructed according to the principles of the present invention may be at least one polymer such as PVKs represented by Formula 1, phenoxazine based polymer represented by Formula 1a, or triphenylamine based polymer.

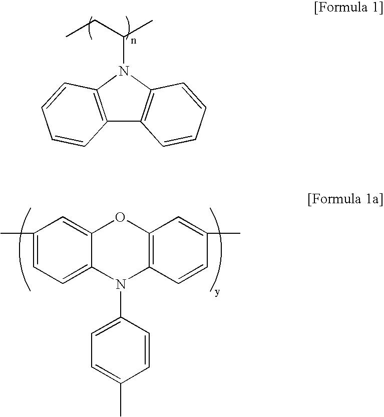

The molecular weight of the polymers are in the range of 25,000 to 50,000.

The triphenylamine based polymer may be TPDPES, TPDPEK (Poly(N,N′-bis(4-butylphenyl)-N,N′-bis(phenyl)benzidine derivatives) or the like. The phenoxazine based polymer may be a polymer shown in Formula 2, Formula 4, or the like.

A method of manufacturing an OLED according to the principles of the present invention now will be described with reference to the OLED shown in FIG. 1D.

First, a first electrode is formed by coating a material on the upper surface of a substrate using a deposition or sputtering method. The material for the first electrode has a high work function. The first electrode can be an anode. The substrate can be an organic substrate or a smooth, waterproof, transparent plastic substrate, but any substrate that is typically used for a general OLED can be used. Also, transparent, highly conductive material such as indium tin oxide (ITO), indium zinc oxide (IZO), tin oxide (SnO₂), or zinc oxide (ZnO) can be used as the material for the first electrode.

A hole transport layer (HTL) is then formed on the upper surface of the first electrode by various methods such as vacuum-deposition, spin coating, casting, Langmuir-Blodgett (LB), or the like. When the HTL is formed by vacuum-deposition, the deposition conditions depend on the compounds used as a material for the HTL, the structure of the HTL, and the thermal property of the HTL. The deposition temperature is preferably in the range of 100° C. to 500° C., the pressure is in the range of 10⁻⁸ torr to 10⁻³ torr, the deposition rate is in the range of 0.01 Å/sec to 100 Å/sec, and the thickness of the HTL is in the range of 10 Å to 5 μm.

When the HTL is formed by spin coating, the deposition conditions depend on the compounds used as a material for the HTL, the structure of the HTL, and the thermal properties of the HTL. The revolution per minute (rpm) of the spinner is preferably in the range of 2000 rpm to 5000 rpm. After the step of spin coating, a step of baking may follow. The baking temperature may be in the range of 50° C. to 250° C.

Materials that can be used to form the HTL of the present invention are not particularly limited, and any material that is typically used for a HTL can be used. For example, carbazole derivatives such as polyvinylcarbazole (PVK) which is represented by the Formula 1, or PEDOT/PSS (poly(3, 4-ethylenedioxythiophene)/polystyreneparasulfonate) may be used.

The thickness of the HTL may be in the range of about 5 nm to 100 nm, preferably in the range of about 10 nm to 60 nm. When the thickness of the HTL is less than 5 nm, hole transport properties of the HTL may not be sufficient. When the thickness of the HTL is greater than 100 nm, driving voltage of the polymer OLED may increase.

The emission layer (EML) is then formed on the upper surface of the HTL using various methods such as spin coating, casting, or the like. When the EML is formed by spin coating or casting, the coating conditions of each method depend on the compounds used for the EML, but are generally the same as those used for forming the HTL.

Materials that can be used to form the EML are not particularly limited, and include, for example, compounds represented by Formula 2 to Formula 4.

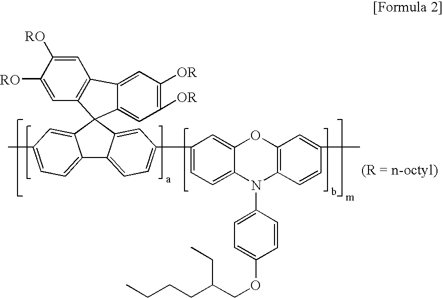

In the Formula 2, m is a real number in the range of 10 to 150, a is 80 to 99 mole %, and b is 1 to 205 mole %.

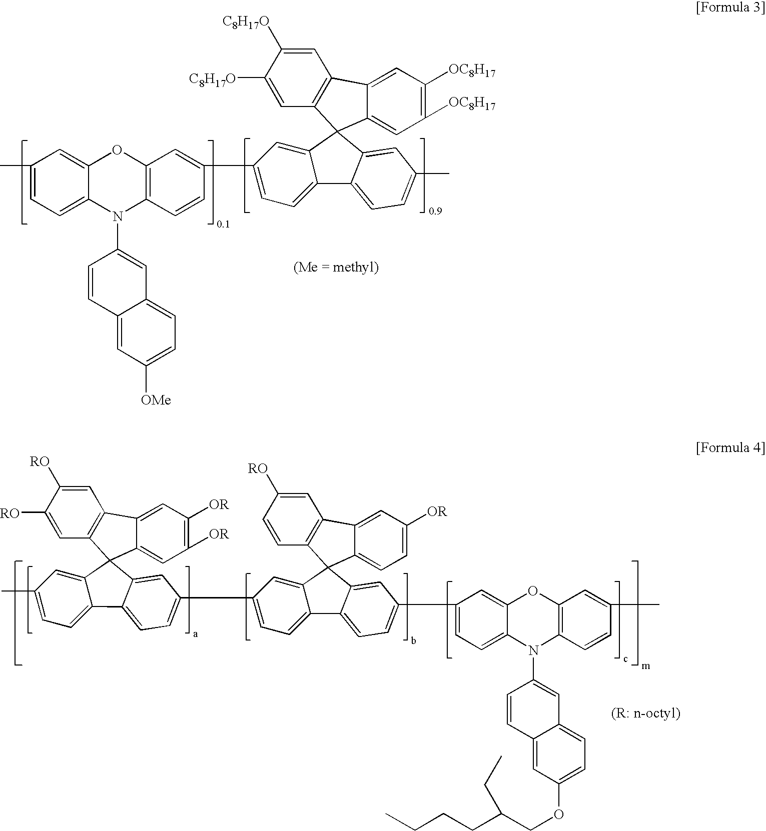

In Formula 4, m is a real number in the range of 10 to 150, a is 80 to 95 mole %, b is 5 to 15 mole %, and c is 5 to 15 mole %.

Various dopants which are known may be used as a material for forming the EML, as well as the compounds described above according to an embodiment of the present invention. For example, IDE102 or IDE105 available from Idemitsu Kosan Co., Ltd, or C545T available Hayashibara Co., Ltd can be used as a fluorescent dopant. Furthermore, PtOEP which is a red phosphorescent dopant, Ir(PPy)₃(PPy=2-phenylpyridine) which is a green phosphorescent dopant, F2Irpic which is a blue phosphorescent dopant, or RD 61 available from UDC Co., Ltd which is a red phosphorescent dopant can be used as a phosphorescent dopant.

The dosage of the dopants is not particularly limited, but is generally in the range of 0.01 to 15 parts by weight relative to 100 parts by weight of the total host material.

The thickness of the emission layer may be in the range of about 10 nm to 100 nm, and preferably in the range of about 20 nm to 60 nm. When the thickness of the emission layer is less than 10 nm, the EL efficiency may be lowered. When the thickness of the emission layer is greater than 100 nm, the driving voltage of the polymer OLED may increase.

The second electrode may be formed on the upper surface of the EML using a method such as vacuum-deposition or spin coating. The second electrode can be used as a cathode. Materials that are used for forming the second electrode include metals having a low work function, alloys, conductive compounds or mixtures thereof. More specific examples of materials used for forming the second electrode include lithium (Li), magnesium (Mg), aluminum (Al), aluminum-lithium (Al—Li), calcium (Ca), magnesium-indium (Mg—In), magnesium-silver (Mg—Ag), or other like metals. Furthermore, a transmissive cathode formed of ITO or IZO may be used to manufacture a top-emission type device.

The polymer OLEDs according to the embodiments of the present invention can further include layers described below.

A hole injection layer (HIL) may be formed using various methods such as spin coating and casting. When the HIL is formed by spin coating, the coating conditions depend on the compounds used to form the HIL, and the structure and thermal properties of the HIL. It is, however, preferred that the rpm of the spinner is in the range of 2000 rpm to 5000 rpm and the thermal treatment temperature for removing solvents is in the range of 80° C. to 200° C.

Materials for the HIL are not particularly limited, but include, for example, soluble conductive polymers such as Pani/DBSA (Polyaniline/Dodecylbenzenesulfonic acid) represented by Formula 5, and PEDOT/PSS (Poly(3,4-ethylenedioxythiophene)/Poly(4-styrenesulfonate) represented by Formula 6, and PANI/PSS (Polyaniline)/Poly(4-styrenesulfonate)

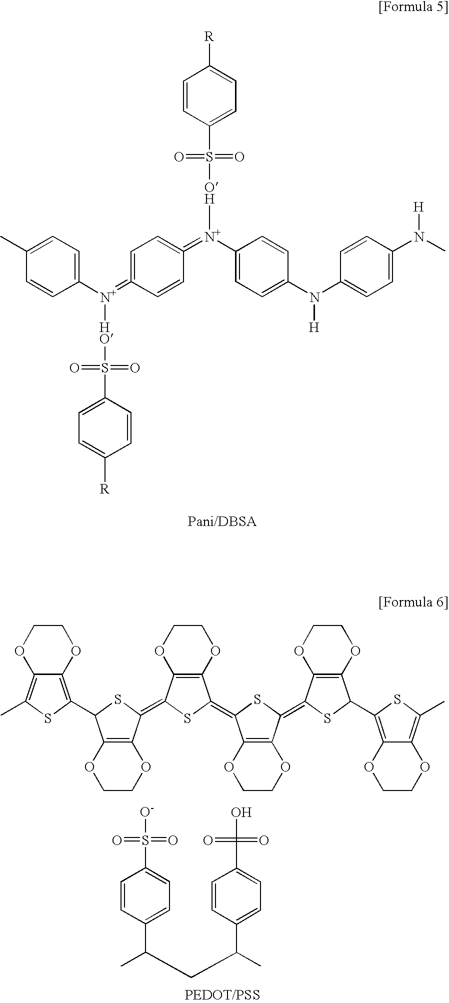

The thickness of the HIL may be in the range of about 100 Å to 10000 Å, preferably in the range of about 100 Å to 1000 Å. When the thickness of the HIL is less than 100 Å, sufficient hole injection properties may not be obtained. When the thickness of the HIL is greater than 10000 Å, the driving voltage of the polymer OLED may increase.

A hole blocking layer (HBL) may be formed on the upper surface of the emission layer (EML) using a method such as spin coating, casting, or Langmuir-Blodgett (LB), in order to prevent triplet exitons or holes from diffusing into the electron transport layer (ETL) when a phosphorescent dopant is also used in the EML. When the HBL is formed by spin coating, the coating conditions depend on the compounds used for the HBL, but are generally the same as those used for forming the HIL.

Known HBL materials, available for the HBL of the polymer OLEDs of the present invention, are, for example, oxadiazole derivatives, triazole derivatives, phenantroline derivatives, or BCP described in JP11-329734(A1).

The thickness of the HBL may be in the range of about 50 Å to 1000 Å, preferably in the range of about 100 Å to 300 Å. When the thickness of the HBL is less than 50 Å, sufficient hole blocking properties may not be obtained. When the thickness of the HBL is greater than 1000 Å, the driving voltage of the polymer OLED may increase.

Then an electron transport layer (ETL) can be formed on the upper surface of the HBL using various methods such as vacuum-deposition, spin coating and casting. When the ETL is formed by vacuum-deposition or spin coating, the conditions of vacuum-deposition or spin coating depend on the compounds used to form the ETL, but are generally the same as those used for forming the HIL. The ETL has a function of safely transporting electrons injected from an electron injection electrode (cathode). Known ETL materials can be used for the ETL, such as quinoline derivatives, and more particularly, tris(8-hydroxyquinolinate)aluminum (Alq₃), or TAZ represented by Formula 7.

### [Formula 7]

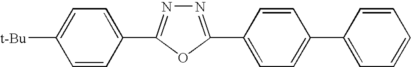

The thickness of the ETL may be in the range of about 100 Å to 1000 Å, preferably in the range of about 200 Å to 500 Å. When the thickness of the ETL is less than 100 Å, sufficient electron transport properties may not be obtained. When the thickness of the ETL is greater than 1000 Å, the driving voltage of the polymer OLED may increase.

An electron injection layer (EIL), which has a function of facilitating the injection of electron from a cathode, can also be stacked on the upper surface of the ETL, and the materials that can be used for the EIL are not particularly limited. Any compounds known as an EIL forming material, such as LiF, NaCl, CsF, BaO and the like, can be used as an EIL of the polymer OLEDs of the present invention. The conditions for the deposition of EIL depend on the compound used to form the EIL, but generally they can be the same as those used for the formation of the HIL.

The thickness of the EIL may be in the range of about 1 Å to 100 Å, preferably in the range of about 5 Å to 50 Å. When the thickness of the EIL is less than 1 Å, sufficient electron injection properties may not be obtained. When the thickness of the EIL is greater than 100 Å, the driving voltage of the polymer OLED may increase.

The polymer OLEDs of the present invention include OLEDs having various structures, and is not limited to the OLED having the structure of first electrode, hole transport layer (HTL), emission layer (EML) and second electrode, as shown in FIG. 1D

Hereinafter, the present invention will be described with reference to the following examples. The following examples are for illustrative purposes only and are not intended to limit the scope of the invention.

### EXAMPLE 1

A polymer OLED having the following structure was manufactured using PVK as a dopant of an EML: ITO/(PEDOT:PSS) (50 nm)/Formula 2+PVK (70 nm)/BaF₂ (4 nm)/Ca (2 nm)/Al (150 nm).

As an anode, a 15Ω/cm² (1500 Å) ITO glass substrate from Corning Inc. was cut into pieces of 50 mm×0.7 mm, cleaned by ultrasonic agitation in a mixture of pure water and isopropyl alcohol for 5 minutes, and then was cleaned with UV radiation and O₃ for 10 minutes before use. PEDOT:PSS was coated on the glass substrate and baked at 120° C. for 10 minutes to form a HTL having a thickness of 500 Å. Subsequently, Formula 2+PVK (prepared in a ratio of 1:1 by weight of Formula 2 to PVK) was spin-coated, and was heat-treated at 200° C. for 1 hour to form an EML having a thickness of 700 Å. Then, (BaF₂4 nm/Ca2 nm/Al150 nm cathode) was vacuum-deposited on the EML to manufacture the polymer OLED shown in FIG. 1D, which was designated sample A.

### EXAMPLE 2

A polymer OLED was manufactured in the same method as described in Example 1 except that Formula 3+PVK, instead of Formula 2+PVK, was used to form an EML.

### EXAMPLE 3

A polymer OLED was manufactured in the same method as described in Example 1 except that the EML included 0.1 weight % of PVK, which is a hole transport material, with respect to the total weight of the EML.

### EXAMPLE 4

A polymer OLED was manufactured in the same method as described in Example 1 except that the EML included 5 weight % of PVK, which is a hole transport material, with respect to the total weight of the EML.

### EXAMPLE 5

A polymer OLED was manufactured in the same method as described in Example 1 except that NPB (N,N′-Dis (naphthalen-l-yl)-N, N′-diphenyl-benzidine) having a hole mobility of 10⁻⁵ cm²V⁻¹s⁻¹ was used as a hole transport material instead of PVK.

### EXAMPLE 6

A polymer OLED was manufactured in the same method as described in Example 1 except that H5 (poly-spirofluorene and phenoxazine derivative, Formula 2, a:b=1:1) having a hole mobility of 10⁻⁷ cm²V⁻¹s⁻¹ was used as a hole transport material instead of PVK.

### EXAMPLE 7

A polymer OLED was manufactured in the same method as described in Example 2 except that NH5 (poly-spirofluorene and phenoxazine derivative, Formula 3) having a HOMO energy level of −5.5 eV was used as a transport material instead of PVK.

### EXAMPLE 8

A polymer OLED was manufactured in the same method as described in Example 1 except that Nafion (perfluorinated sulfonic acid group in Formula 8) having a HOMO energy level of −5.9 eV was used as a transport material instead of PVK.

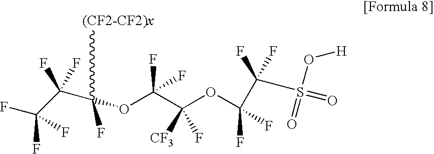

### COMPARATIVE EXAMPLE 1

A polymer OLED was manufactured in the same method as described in Example 1 except that Formula 2 alone, instead of Formula 2+PVK, was used to form an EML.

### COMPARATIVE EXAMPLE 2

A polymer OLED was manufactured in the same method as described in Example 1 except that Formula 3 alone, instead of Formula 2+PVK, was used to form an EML.

Evaluation Example: Evaluation of properties of Examples 1 to 8 and Comparative Examples 1 and 2

Electron density, brightness, and color purity of the polymer OLEDs manufactured in Examples 1 to 8, and Comparative Examples 1 and 2 were measured using PR650 (Spectroscan) Source Measurement Unit. The results are shown in Table 1.

TABLE 1

| | Brightness after 80 | | |
|---|---|---|---|
| | hours (%, | CIE coordinates | Current efficiency |
| Example | @1200 unit) | (x, y) | at 5 V (cd/A) |
| Example 1 | 75.5 | (0.17, 0.32) | 6.41 |
| Example 2 | 78.3 | (0.17, 0.32) | 5.42 |
| Example 3 | 74.1 | (0.17, 0.32) | 6.65 |
| Example 4 | 73.3 | (0.17, 0.32) | 6.52 |
| Example 5 | 74.5 | (0.17, 0.31) | 5.82 |
| Example 6 | 77.8 | (0.17, 0.32) | 6.75 |
| Example 7 | 74.5 | (0.17, 0.33) | 6.70 |
| Example 8 | 73.1 | (0.17, 0.32) | 8.22 |
| Comparative | 68.6 | (0.17, 0.34) | 6.70 |
| Example 1 | | | |
| Comparative | 70.4 | (0.17, 0.32) | 5.87 |
| Example 2 | | | |

As shown in Table 1, the polymer OLEDs manufactured in Examples 1-8, in which the EML includes the hole transport material, exhibit improvements of brightness, color purity, and current efficiency, as compared to those manufactured in Comparative Examples 1-2. The improvement of brightness means increased lifetime. The color coordinate shows that the color shifts toward purer blue. The improved color purity means that the recombination zone moved toward the cathode. The improvement of current efficiency, or current density, as shown in Table 1 means an increase of hole current along with an increase of hole mobility.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A polymer organic light-emitting device comprising:
a first electrode;
a second electrode; and
an emission layer disposed between the first electrode and the second electrode, the emission layer including both of an emission material and a hole transport material.

2. The polymer organic light-emitting device of claim 1, comprised of the hole transport material having a hole mobility between about 10⁻⁵ cm²V⁻¹s⁻¹ and about 10⁻⁷ cm²V⁻¹s⁻¹, and having a highest occupied molecular orbital energy level between about −5.5 eV and about −5.9 eV.

3. The polymer organic light-emitting device of claim 1, wherein the hole transport material has a glass transition temperature between about 100° C. and about 300° C.

4. The polymer organic light-emitting device of claim 1, wherein the content of the hole transport material in the emission layer is between about 0.1 weight % and about 10 weight % of the total weight of the emission layer.

5. The polymer organic light-emitting device of claim 1, wherein the emission layer has either a single-layered structure or a multi-layered structure.

6. The polymer organic light-emitting device of claim 5, wherein the emission layer having the single-layered structure has a thickness between about 50 nanometers and about 120 nanometers.

7. The polymer organic light-emitting device of claim 1, comprised of the emission layer comprising:
a first emission layer including both of an emission material and a hole transport material; and
a second emission layer including an emission material, the total thickness of the emission layer being in the range of about 60 nanometers to about 120 nanometers, the thickness of the first emission layer being in the range of about 10 nanometers to about 50 nanometers.

8. The polymer organic light-emitting device of claim 1, further comprising a layer selected from the group consisting of a hole injection layer, a hole transport layer, an electron blocking layer, a hole blocking layer, an electron transport layer, and an electron injection layer, the layer being disposed between the first electrode and the second electrode.

9. The polymer organic light-emitting device of claim 1, further comprising a stack selected from the group consisting of:
a stack of a hole transport layer disposed between the first electrode and the emission layer;
a stack of a hole injection layer disposed between the first electrode and the emission layer, an electron transport layer disposed between the emission layer and the second electrode, and an electron injection layer disposed between the electron transport layer and the second electrode;
a stack of a hole injection layer disposed between the first electrode and the emission layer, a hole transport layer disposed between the hole injection layer and the emission layer, an electron transport layer disposed between the emission layer and the second electrode, and an electron injection layer disposed between the electron transport layer and the second electrode; and
a stack of a hole injection layer disposed between the first electrode and the emission layer, a hole transport layer disposed between the hole injection layer and the emission layer, a hole blocking layer disposed between the emission layer and the second electrode, an electron transport layer disposed between the hole blocking layer and the second electrode, and an electron injection layer disposed between the electron transport layer and the second electrode.

10. The polymer organic light-emitting device of claim 1, wherein the emission layer contains a phosphorescent dopant or a fluorescent dopant, each of the phosphorescent dopant and the fluorescent dopant including red, green, blue or white dopant.

11. The polymer organic light-emitting device of claim 1, wherein the hole transport material is a polymer selected from the group consisting of PVKs, phenoxazine based polymer, and triphenylamine based polymer.

12. A polymer organic light-emitting device comprising:
a first electrode;
a second electrode;
a first emission layer disposed between the first electrode and the second electrode, the first emission layer including both of an emission material and a hole transport material; and
a second emission layer disposed between the first electrode and the second electrode, the second emission layer including an emission material.

13. The polymer organic light-emitting device of claim 12, comprised of the second emission layer disposed between the first emission layer and the second electrode.

14. The polymer organic light-emitting device of claim 12, wherein the total thickness of the first emission layer and the second emission layer is in the range of about 60 nanometers to about 120 nanometers, and the thickness of the first emission layer is in the range of about 10 nanometers to about 50 nanometers.

15. The polymer organic light-emitting device of claim 12, further comprising a layer selected from the group consisting of a hole injection layer, a hole transport layer, an electron blocking layer, a hole blocking layer, an electron transport layer, and an electron injection layer, the layer being disposed between the first electrode and the second electrode.

16. The polymer organic light-emitting device of claim 12, wherein the content of the hole transport material in the first emission layer is between about 0.1 weight % and about 10 weight % of the total weight of the first emission layer.
